(19) United States
(12) Patent Application Publication
(10) Pub. No.: US 2011/0167326 A1
(43) Pub. Date: Jul. 7, 2011

(54) RELAY APPARATUS AND WIRELESS COMMUNICATION SYSTEM

(75) Inventors: Kenichi Kuri, Kanagawa (JP); Katsuhiko Hiramatsu, Kanagawa (JP); Seigo Nakao, Kanagawa (JP); Ayako Horiuchi, Kanagawa (JP)

(73) Assignee: PANASONIC CORPORATION, Osaka (JP)

(21) Appl. No.: 13/062,889

(22) PCT Filed: Sep. 11, 2009
(86) PCT No.: PCT/JP2009/004527

§ 371 Date: Mar. 8, 2011

(30) Foreign Application Priority Data
Sep. 12, 2008 (JP) 2008-235357

(51) Int. Cl. H03M 13/09; G06F 11/10

(52) U.S. Cl. 714/807; 714/E11.032

(57) ABSTRACT

A relay station and a wireless communication system wherein novel retransmission control is achieved in cases when a TTI-bundling technique and a relay technique are used in communication between a terminal and a base station. A relay station (300) relays wireless communication between a terminal that transmits a wireless signal in which code words obtained by encoding a single set of transmission data have been mapped to a TTI bundle consisting of a plurality of TTIs, and a base station that receives the wireless signal and transmits error detection information related to the code word transmitted in the tail TTI of the TTI bundle. At the relay station (300), a control information generating unit (309) transmits error detection information related to the code word transmitted in the front TTI of the TTI bundle.

### TECHNICAL FIELD

The present invention relates to a relay apparatus and a radio communication system.

### BACKGROUND ART

Third-generation mobile communication services have been launched, and multimedia communication such as data communication or video communication is increasingly popular. It is expected that demand for communication in all circumstances increases, and therefore coverage area is expanded in future.

Therefore, with 3GPP-LTE (Long Term Evolution), introduction of a technique referred to as “TTI-bundling” has been agreed in order to expand coverage for uplink transmission from terminals (UEs: User Equipments) to a base station (eNB: enhanced Node B). With TTI-bundling, a terminal residing near a cell edge bundles a plurality of TTIs in uplink transmission, and this is regarded as one HARQ process. Then, small data such as VoIP data is encoded with a low coding rate, a resultant codeword is mapped to a plurality of TTIs and transmitted to improve the uplink reception quality in a base station (see Non-Patent Literature 1). Hereinafter, a plurality of bundled TTIs may be referred to as “TTI bundle.”

FIG. 1 explains a retransmission process in a communication system adopting the TTI-bundling technique. FIG. 1 shows a case in which three TTIs are bundled.

In FIG. 1, a terminal bundles TTIs 0 to 2 to transmit data to a base station. Here, the terminal transmits a codeword mapped to at least TTI 0, adding CRC to the codeword. The base station receives and decodes this data. The base station performs error detection on only data transmitted in the first TTI using CRC check. Then, upon detecting an error, the base station transmits NACK to the terminal. Upon receiving the NACK, the terminal retransmits data in a retransmission-scheduled period.

Here, when TTIs are assigned to uplink data from the terminal at the first transmission, retransmission-scheduled periods are determined at this time. In FIG. 1, the retransmission-scheduled periods corresponding to TTIs 0 to 2 are TTIs 8 to 10. Therefore, the terminal performs retransmission in TTIs 8 to 10. Here, an interval (here, eight TTIs) between transmission-scheduled periods (including the first transmission period and a retransmission-scheduled period) is determined based on the round trip time of a HARQ process (HARQ-RTT) between a terminal residing near a cell edge and a base station. A HARQ-RTT is determined based on the time to propagate transmission signals (the first transmission signal and NACK) between a terminal and a base station, and the time to perform processing, including transmission signal generation processing, in the terminal and the base station.

However, the above-described conventional communication system has a problem that unnecessary retransmission is performed. That is, as shown in FIG. 2, a base station performs error detection on only data transmitted in the first in a group of bundled TTIs, and transmits ACK/HACK to a terminal, based on this result of the detection. Therefore, even if an error is corrected in process of decoding subsequent TTIs in a group of bundled TTIs (that is, in a state in which ACK should be transmitted), when a base station has already transmitted NACK to a terminal, the terminal will perform retransmission processing. This causes a problem that the system throughput decreases.

By the way, standardization of 3GPP LTE-Advanced that realizes faster speed of communication than by 3GPP LTE, has been launched (see Non-Patent Literature 2). With this 3GPP LTE-Advanced, studies are underway to place a relay station (RN: relay node) between each terminal and a base station in order to expand uplink transmission coverage.

### CITATION LIST

### Non-Patent Literature

[NPL 1] R1-081103, RAN1, “Reply LS on Uplink Coverage for LTE,” 3GPP TSG RAN WG1 #52, Sorrento, Feb. 11-15, 2008
[NPL 2] R1-081722, Samsung, “Future 3GPP Radio Technologies for LTE-Advanced,” 3GPP TSG RAN WG1 #53, Kansas City, May. 5-9, 2008

### SUMMARY OF INVENTION

### Technical Problem

However, with 3GPP LTE-Advanced, automatic retransmission control has not been studied yet. As described above, with 3GPP LTE, effective retransmission control cannot be performed in communication between terminals and a base station in a radio communication system so far, and if relay stations are added to this, innovation is required to efficiently perform automatic retransmission control.

It is therefore an object of the present invention to provide a relay apparatus and a radio communication system to realize new retransmission control when a TTI-bundling technique and a relay technique are adopted for communication between terminals and a base station.

### Solution to Problem

The relay apparatus according to the present invention adopts a configuration to include:

The radio communication system according to the present invention adopts a configuration to include: a relay apparatus that relays radio communication between a terminal and a base station, the terminal transmitting a radio signal in which a codeword obtained by encoding one transmission data is mapped to a transmission time interval (TTI) bundle composed of a plurality of transmission time intervals, and the base station receiving the radio signal and transmitting error detection information about the codeword transmitted in a first transmission time interval in the transmission time interval bundle. The relay apparatus includes a decoding section that decodes, per transmission time interval, the codeword mapped to the transmission time interval bundle contained in a received radio signal; an error detecting section that performs error detection on each decoding result; and a transmission section that transmits error detection result information about the codeword transmitted in a second transmission time interval before at least the first transmission time interval in the transmission time interval bundle.

### Advantageous Effects of Invention

According to the present invention, it is possible to provide a relay apparatus and a radio communication system to realize new retransmission control when a TTI-bundling technique and a relay technique are adopted for communication between terminals and a base station.

### BRIEF DESCRIPTION OF DRAWINGS

FIG. 1 explains a retransmission process in a communication system adopting the TTI-bundling technique;

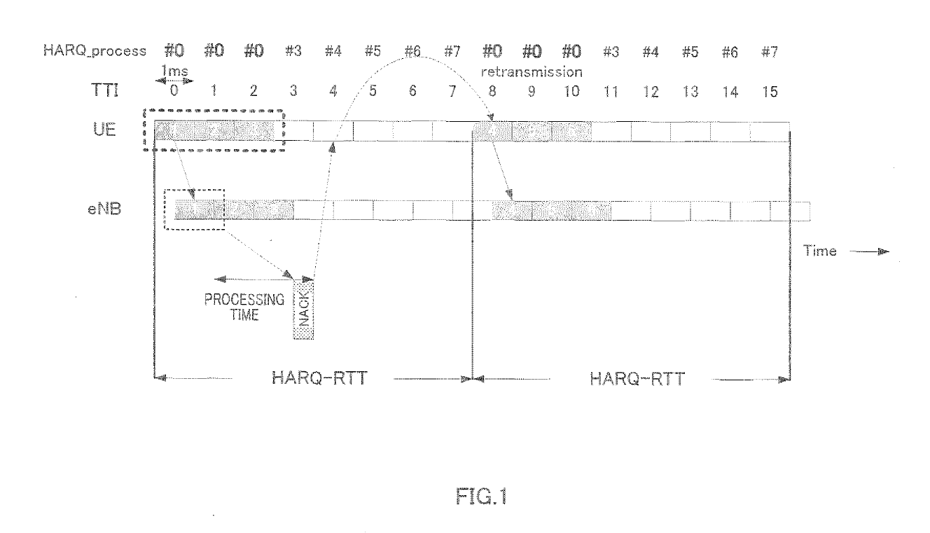

FIG. 2 explains a retransmission process in a communication system adopting the TTI-bundling technique;

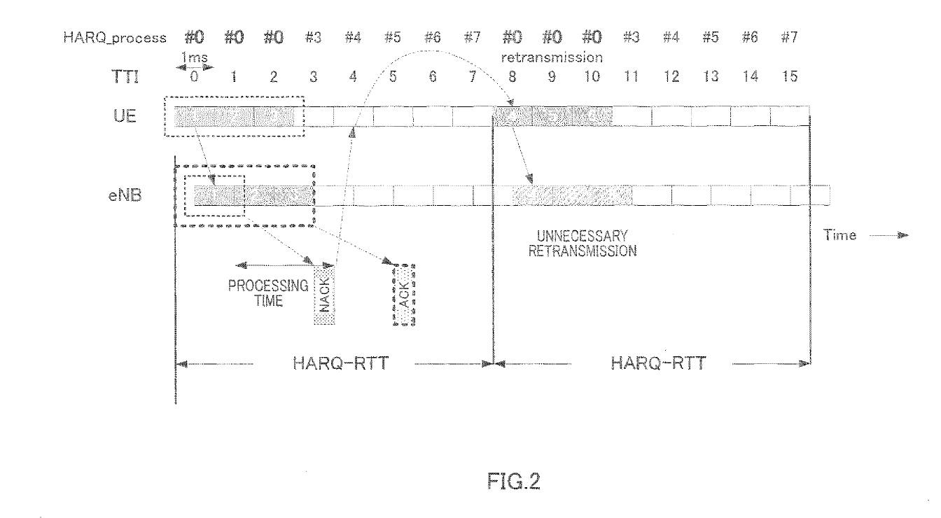

FIG. 3 is a block diagram showing a configuration of a radio communication system according to Embodiment 1 of the present invention;

FIG. 4 is a block diagram showing a configuration of a terminal according to Embodiment 1 of the present invention;

FIG. 5 is a block diagram showing a configuration of a base station according to Embodiment 1 of the present invention;

FIG. 6 is a block diagram showing a configuration of a relay station according to Embodiment 1 of the present invention;

FIG. 7 explains operations of a terminal, a base station and a relay station according to Embodiment 1 of the present invention;

FIG. 8 explains a state in which a codeword is stored in a circular buffer, and a method of reading the codeword from the circular buffer (at the time of the first transmission);

FIG. 9 explains a state in which a codeword is stored in a circular buffer, and a method of reading the codeword from the circular buffer (at the time of retransmission);

FIG. 10 explains a comparative technique;

FIG. 11 explains operations of a terminal, a base station and a relay station according to Embodiment 2 of the present invention;

FIG. 12 explains operations of a terminal, a base station and a relay station according to Embodiment 3 of the present invention;

FIG. 13 explains operations of a terminal, a base station and a relay station according to Embodiment 4 of the present invention; and

FIG. 14 explains operations of a terminal, a base station and a relay station according to Embodiment 4 of the present invention.

### DESCRIPTION OF EMBODIMENTS

Now, embodiments of the present invention will be described in detail with reference to the accompanying drawings. Here, in the embodiments, the same components are assigned the same reference numerals and overlapping descriptions will be omitted.

### Embodiment 1

### [The Configuration of a Radio Communication System]

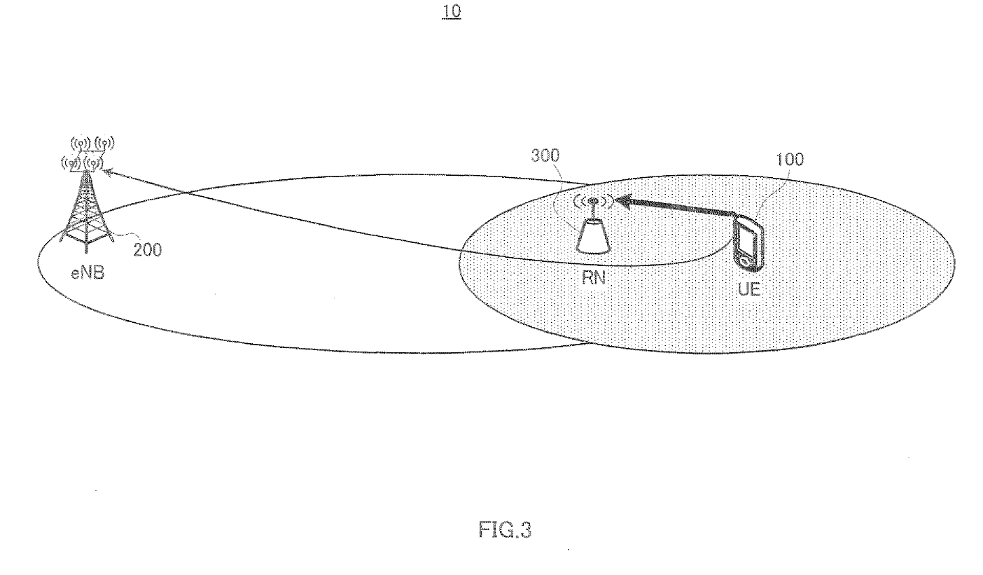

FIG. 3 explains the configuration of a radio communication system according to Embodiment 1 of the present invention. In FIG. 3, radio communication system 10 has terminal 100, base station 200 and relay station 300. Although FIG. 3 only shows one terminal 100, one base station 200 and one relay station 300 for ease of explanation, actually, a plurality of relay stations 300 are distributed and arranged in the cell of one base station 200. Therefore, in radio communication system 10, an environment is realized in which the separation distance between terminal 100 and relay station 300 and the separation distance between base station 200 and relay station 300 are likely to be shorter than the separation distance between terminal 100 and base station 200. Therefore, in radio communication system 10, it is possible to consider that the communication quality between terminal 100 and relay station 300 and the communication quality between base station 200 and relay station 300 are higher than the communication quality between terminal 100 and base station 200, regardless of the position of terminal 100.

[The configuration of Terminal 100]

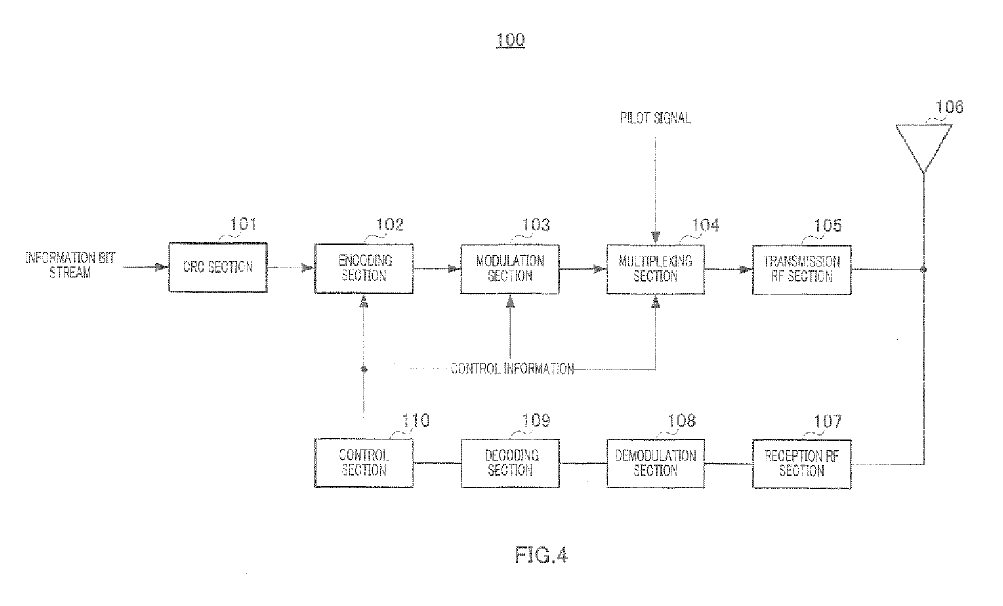

FIG. 4 is a block diagram showing the configuration of terminal 100 according to Embodiment 1 of the present invention. In FIG. 4, terminal 100 has CRC section 101, encoding section 102, modulation section 103, multiplexing section 104, transmission RF section 105, antenna 106, reception RF section 107, demodulation section 108, decoding section 109 and control section 110.

CRC section 101 performs error detection (CRC: cyclic redundancy check) and encoding on an information bit stream, and outputs a resultant information bit stream to which CRC parity bits have been added, to encoding section 102.

Encoding section 102 has a circular buffer (not shown). Encoding section 102 performs turbo encoding on the information bit stream with CRC parity bits, with a mother coding rate and stores a resultant codeword in the circular buffer. Encoding section 102 extracts an output codeword matching control information received from control section 110, from codewords stored in the circular buffer, and outputs it to modulation section 103. The control information received from control section 110 includes transmission type information (including a coding rate) indicating transmission by TTI-bundling, a new transmission command, a retransmission preparation command, a retransmission execution command, M-ary modulation number information, or assigned frequency resource information.

At the time of new (the first) transmission, encoding section 102 extracts an output codeword matching the coding rate contained in control information received from control section 110, from codewords stored in the circular buffer, and outputs it to modulation section 103. Encoding section 102 performs processing associated with preparation for retransmission, retransmission and transmission of new data (including processing to delete the codeword for the data transmitted last time from the circular buffer), based on control information received from control section 110. Processing in encoding section 102 will be described in detail later.

Modulation section 103 generates a data symbol by modulating the codeword received from encoding section 102 with the M-ary modulation number contained in the control signal received from control section 110, and outputs the resultant data symbol to multiplexing section 104.

Multiplexing section 104 multiplexes the data symbol received from modulation section 103, the control information received from control section 110 and a pilot signal, and forms a multiplexed signal, which is a baseband signal. At this time, the data symbol is placed in the assigned frequency indicated by assigned frequency resource information contained in the control information received from control section 110.

Transmission RF section 105 transforms the multiplexed signal to a frequency domain signal, and transmits a resultant RF signal via antenna 106.

Reception RF section 107 receives a control signal (including assignment information or an ACK/NACK signal) transmitted from after-mentioned base station 200, and an ACK/NACK signal transmitted from after-mentioned relay station 300 via antenna 106, and transforms a received signal to a frequency domain signal to obtain a baseband signal. This baseband signal is outputted to demodulation section 108.

Demodulation section 108 demodulates a control signal contained in the baseband signal received from reception RF section 107 and an ACK/NACK signal from relay station 300, and outputs a demodulated control signal and a modulated ACK/NACK signal to decoding section 109.

Decoding section 109 decodes the demodulated control signal and ACK/NACK signal, and outputs resultant control information and ACK/NACK information to control section 110.

Control section 110 specifies a coding rate, an M-ary modulation number, assigned frequency resources and ACK/NACK information contained in the control information received from decoding section 109. In addition, control section 110 determines whether or not to perform processing, including preparation for retransmission, decision to perform retransmission, retransmission and transmission of new data, based on the specified ACK/NACK information from base station 200 and the specified ACK/NACK information from relay station 300, and outputs control information according to the result of the determination to encoding section 102. In addition, among the specified control information, the coding rate is outputted to encoding section 102, the M-ary modulation number is outputted to modulation section 103, and the assigned frequency resources are outputted to multiplexing section 104.

[The Configuration of Base Station 200]

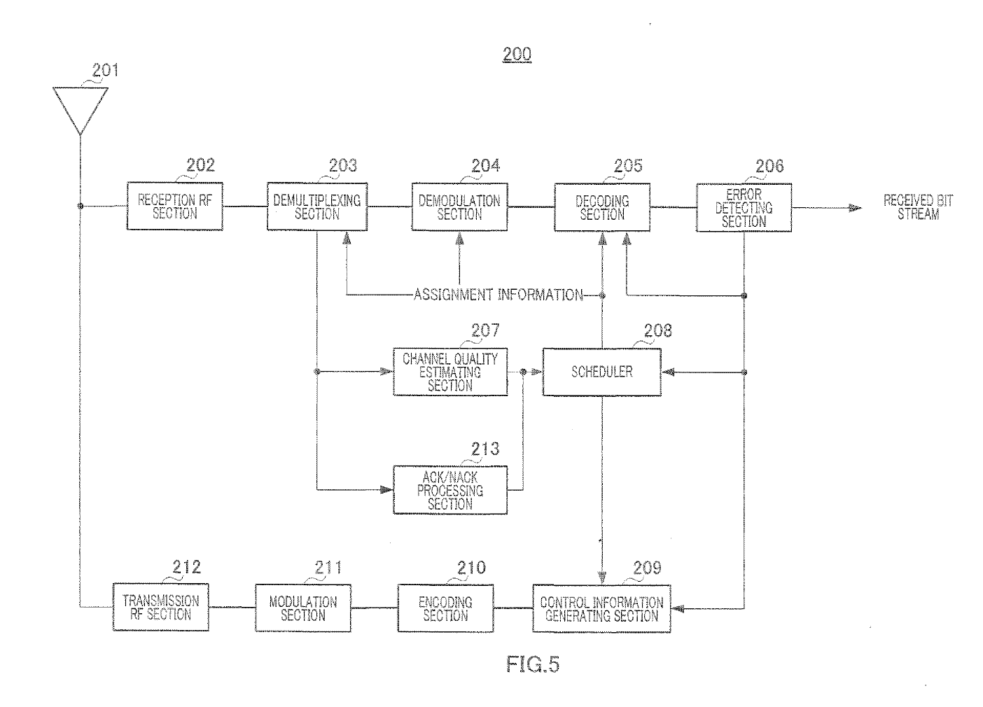

FIG. 5 is a block diagram showing the configuration of base station 200 according to Embodiment 1 of the present invention. In FIG. 5, base station 200 has antenna 201, reception RF section 202, demultiplexing section 203, demodulation section 204, decoding section 205, error detecting section 206, channel quality estimating section 207, scheduler 208, control information generating section 209, encoding section 210, modulation section 211, transmission RF section 212 and ACK/NACK processing section 213.

Reception RF section 202 receives a data signal transmitted from terminal 100 and a data signal transmitted from relay station 300 via antenna 201, and transforms each of the relieved data signals to a frequency domain signal to obtain a baseband signal. This baseband signal is outputted to demultiplexing section 203.

Demultiplexing section 203 demultiplexes the baseband signal received from reception RF section 202 into a data symbol, a received pilot signal and an ACK/NACK signal transmitted from relay station 300. Moreover, demultiplexing section 203 outputs a data symbol matching assigned frequency resource information contained in assignment information received from scheduler 208, to demodulation section 204, outputs the received pilot signal to channel quality estimating section 207 and outputs an ACK/NACK signal transmitted from relay station 300, to ACK/NACK processing section 213.

Demodulation section 204 demodulates the data symbol received from demodulation section 203, according to M-ary modulation number information contained in the assignment information received from scheduler 208.

Decoding section 205 performs error correction decoding on the result of the demodulation received from demodulation section 204, based on coding rate information contained in the assignment information received from scheduler 208 to obtain a decoded bit stream. This obtained decoded bit stream (received data) is stored in a memory (not shown) provided in decoding section 205, and is outputted to error detecting section 206. The result of decoding of the TTI targeted for this decoding in a TTI bundle is used to decode the codeword transmitted in the next TTI. Therefore, in a TTI bundle, the error rate of a codeword transmitted in a later TTI is lower. In addition, only when receiving an ACK signal from error detecting section 206, decoding section 205 discards received data having already been stored in a memory.

Error detecting section 206 performs error detection (CRC) per TTI on the decoded bit stream received from decoding section 205.

When there is an error in the decoded bit stream as a result of error detection, error detecting section 206 generates a NACK signal as a response signal, and, on the other hand, when there is no error in the decoded bit stream, generates an ACK signal as a response signal. This generated ACK/NACK signal is outputted to decoding section 205, scheduler 208 and control information generating section 209. In addition, when there is no error in the decoded bit stream, error detecting section 206 outputs the decoded bit stream as a received bit stream.

Channel quality estimating section 207 estimates channel quality (SINR: signal-to-interference and noise power ratio) from the received pilot signal. The SINR estimation value is outputted to scheduler 208.

ACK/NACK processing section 213 performs reception processing on an ACK/NACK signal transmitted from relay station 300, and outputs an ACK/NACK signal after reception processing to scheduler 208.

Scheduler 208 generates assignment information, based on the SINR estimation value received from channel quality estimating section 207, the ACK/NACK signal received from error detecting section 206 and the ACK/NACK signal from relay station 300, This assignment information includes M-ary modulation number information, coding rate information and assigned resource information. This assignment information is outputted to control information generating section 209, demultiplexing section 203, demodulation section 204 and decoding section 205. Scheduling of retransmission data in scheduler 208 will be described later.

Control information generating section 209 receives an ACK/NACK signal from error detecting section 206. Then, when data transmission is performed using the TTI-bundling technique, control information generating section 209 transmits an ACK/NACK signal for the codeword transmitted in the last TTI in a TTI bundle, according to the detecting timing. Control information generating section 209 generates a control signal frame by combining an ACK/NACK signal and assignment information received from scheduler 208, and transmits this frame via encoding section 210, modulation section 211 and transmission RF section 212.

The control signal frame generated in control information generating section 209 is encoded in encoding section 210, modulated in modulation section 211, transformed to a frequency domain signal in transmission RF section 212, and then transmitted via antenna 201.

[The Configuration of Relay Station 300]

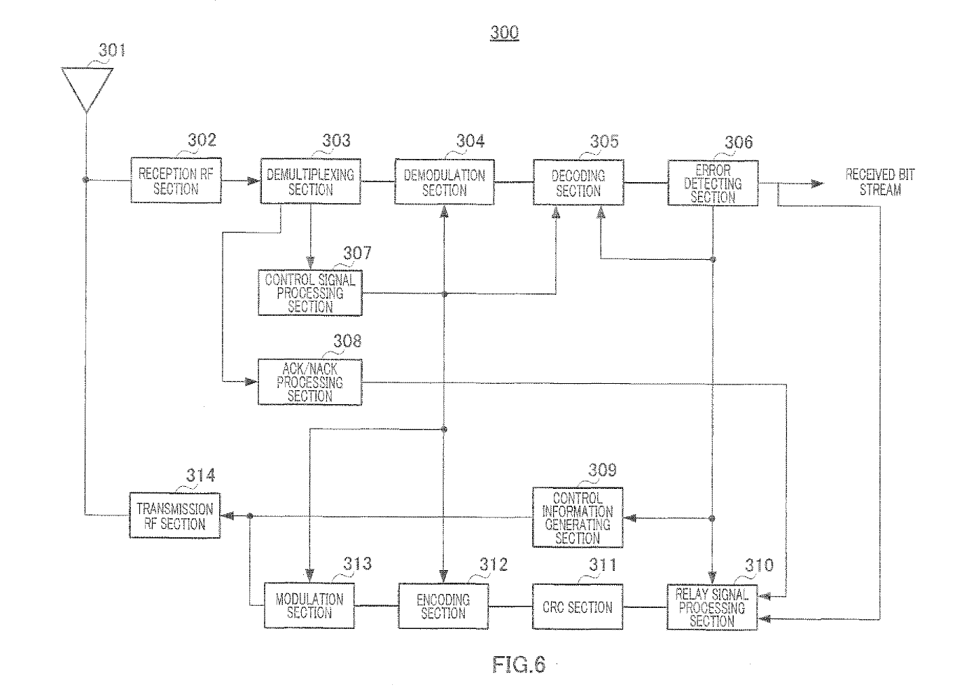

FIG. 6 shows a block diagram showing the configuration of relay station 300 according to Embodiment 1 of the present invention. In FIG. 6, relay station 300 has antenna 301, reception RF section 302, demultiplexing section 303, demodulation section 304, decoding section 305, error correction section 306, control signal processing section 307, ACK/NACK processing section 308, control information generating section 309, relay signal processing section 310, CRC section 311, coding section 312, modulation section 313 and transmission RF section 314.

Reception RF section 302 receives a data signal transmitted from terminal 100 and a control signal (including assignment information and an ACK/NACK signal) transmitted from base station 200 via antenna 301, and transforms each of the received signals to a frequency domain signal to obtain a baseband signal. This baseband signal is outputted to demultiplexing section 303.

Demultiplexing section 303 demultiplexes the base band signal received from reception RF section 302 into a data symbol transmitted from terminal 100 and a control signal transmitted from base station 200. Moreover, demultiplexing section 303 outputs the data symbol to demodulation section 304, and outputs the control signal transmitted from base station 200 to control signal processing section 307 and ACK/NACK processing section 308.

Demodulation section 304 demodulates the data symbol received from demultiplexing section 303, according to M-ary modulation number information contained in assignment information received from control signal processing section 307.

Decoding section 305 obtains a decoded bit stream by performing error correction decoding on the result of the demodulation received from demodulation section 304, based on coding rate information contained in the assignment information received from control signal processing section 307. This obtained bit stream (received data) after decoding is stored in a memory (not shown) provided in decoding section 305, and outputted to error detecting section 306. The result of decoding of the TTI targeted for this decoding in a TTI bundle is used to decode the codeword transmitted in the next TTI. Therefore, in a TTI bundle, the error rate of a codeword transmitted in a later TTI is lower. In addition, only when receiving an ACK signal from error detecting section 306, decoding section 305 discards received data having already been stored in a memory.

Error detecting section 306 performs error detection (CRC) per TTI on the decoded bit stream received from decoding section 305.

When there is an error in the decoded bit stream as a result of error detection, error detecting section 306 generates a NACK signal as a response signal, and, on the other hand, when there is no error in the decoded bit stream, generates an ACK signal as a response signal. This generated ACK/NACK signal is outputted to decoding section 305, control information generating section 309 and relay signal processing section 310. In addition, when there is no error in the decoded bit stream, error detecting section 306 outputs the decoded bit stream as a received bit stream.

Control signal processing section 307 demodulates and decodes a control signal received from demultiplexing section 303, and specifies assignment information contained in the control signal. The assignment information contains a coding rate, an M-ary modulation number and assigned frequency resources. Then, the assignment information is outputted to demodulation section 304, decoding section 305, encoding section 312 and modulation section 313.

ACK/NACK processing section 308 performs reception processing on an ACK/NACK signal contained in the control signal received from demultiplexing section 303, and outputs resultant ACK/NACK information to relay signal processing section 310.

Control information generating section 309 receives an

ACK/NACK signal from error detecting section 306. Then, when data transmission is performed using the TTI-bundling technique, control information generating section 309 transmits an ACK/NACK signal for the codeword transmitted in the first TTI in a TTI bundle, according to the detecting timing.

Relay signal processing section 310 receives an ACK/NACK signal from error detecting section 306 and receives ACK/NACK information from ACK/NACK processing section 308. Then, relay signal processing section 310 determines whether or not to perform relay processing, based on the ACK/NACK signal from error detecting section 306 and the ACK/NACK information from ACK/NACK processing section 308 (that is, ACK/NACK information from base station 200). When it is determined to perform relay processing, relay signal processing section 310 transmits relay information. This relay information is retransmission data to be transmitted by relay signal processing section 310, in the retransmission-scheduled period corresponding to the last TTI in a TTI bundle, instead of terminal 100. Relay processing section 310 will be described in detail later.

CRC section 311 performs error detection coding on relay information, and outputs resultant relay data to which CRC parity hits have been added, to encoding section 312.

Encoding section 312 has a buffer (not shown). Encoding section 312 performs turbo coding on an information bit stream with CRC parity bits, with a mother coding rate, and stores a resultant codeword in the buffer. Encoding section 312 extracts an output codeword matching a relay signal coding rate contained in assignment information received from control signal processing section 307, and outputs it to modulation section 313.

Modulation section 313 generates a data symbol by modulating the codeword received from encoding section 312 with the M-ary modulation number contained in assignment information received from control signal processing section 307, and outputs the obtained data symbol to transmission RE section 314.

Transmission RF section 314 transforms an ACK/NACK signal received from control information generating section 309 to a frequency domain signal, transforms the data symbol received from modulation section 313 to a frequency domain data symbol, and transmits resultant RE signals via antenna 301.

[Descriptions of Operations of Terminal 100, Base Station 200 and Relay Station 300]

### (The First Transmission by Terminal 100)

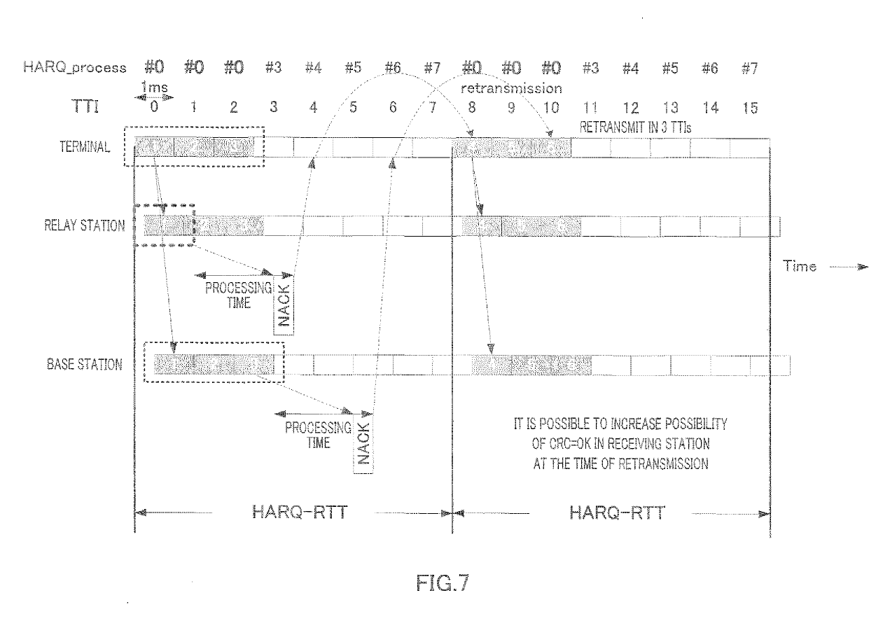

As shown in FIG. 7, terminal 100 bundles TTIs 0 to 2 to transmit data. That is, in terminal 100, encoding section 102 extracts an output codeword matching the coding rate contained in control information received from control section 110, from codewords stored in a circular buffer, and outputs it to modulation section 103.

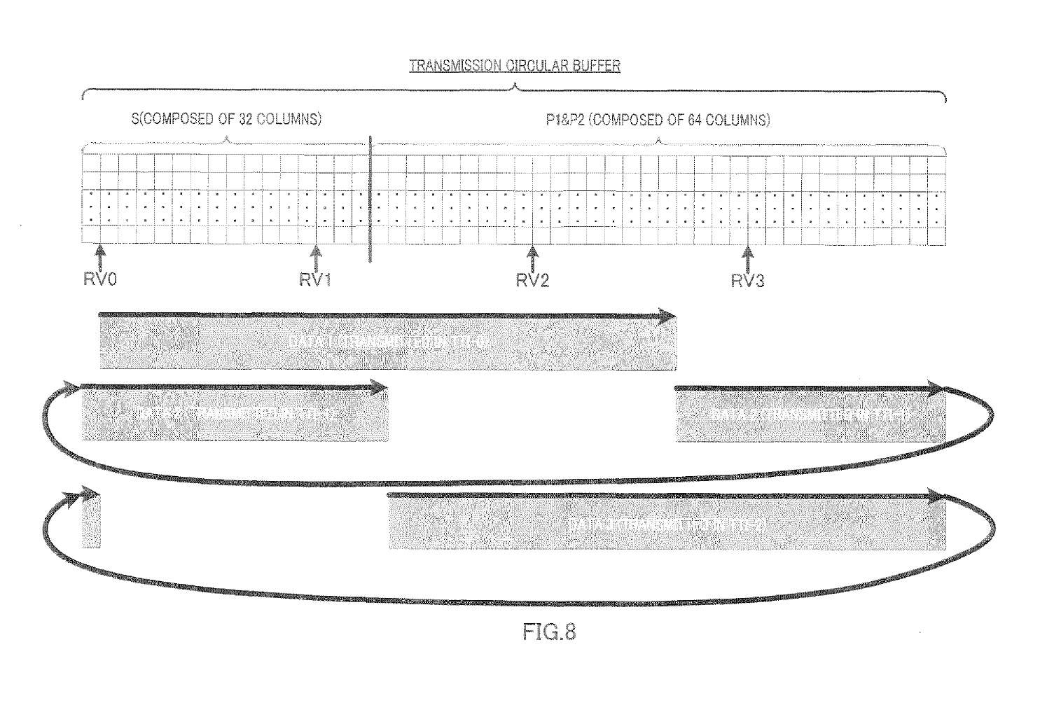

FIG. 8 explains a case in which a codeword is stored in a circular buffer, and a method of reading the codeword from the circular buffer (at the time of the first transmission).

As shown in FIG. 8, the circular buffer is composed of ninety-six columns and stores a codeword. S (composed of thirty-two columns) in the left part is formed with information bits to which CRC parity bits have been added (that is, systematic bits), and P1 and P2 (composed of sixty-four columns) in the right part is formed with parity bits generated by turbo coding. Here, the systematic bit side is defined as the front, and the parity bit side is defined as the back.

Encoding section 102 reads the codeword of a predetermined length from a predetermined reading start position toward the back, as data 1 transmitted in TTI 0, and outputs the codeword to modulation section 103. Here, the predetermined reading start position (RV 0) is the third column from the left in the circular buffer (FIG. 8). In addition, the predetermined length corresponds to sixty-four columns in the circular buffer. Therefore, data 1 is equivalent to part of the circular buffer from the third column to the sixty-sixth column.

Next, encoding section 102 also reads the codeword of a predetermined length (equivalent to data 2 in FIG. 8) from the column following the last column read in data 1, as a reading start position, toward the back, and outputs it to demodulation section 103. Here, when the last column is arrived at in the circular buffer before completion of reading of the codeword of a predetermined length, reading is continued from the first column in the circular buffer Therefore, data 2 is equivalent to the part from the sixty-seventh column to the ninety-sixth column and the part from the first column to the thirty-fourth column in the circular buffer.

Next, encoding section 102 also reads the codeword of a predetermined length (equivalent to data 3 in FIG. 8) from the column following the last column read in data 2, as a reading start position, toward the back, and outputs it to demodulation section 103. Data 3 is equivalent to the part from the thirty-fifth column to the ninety-sixth column and the part from the first column to the second column in the circular buffer. Here, RV (redundancy version) is command information to specify the position in the circular buffer from which a codeword is read. 3GPP LTE defines that RV 0 corresponds to the third column, RV 1 corresponds to the twenty-seventh column, RV 2 corresponds to the fifty-first column and RV 3 corresponds to seventy-fifth column. Then, RV 0 is used at the time of the first transmission.

As described above, as shown in FIG. 7, a plurality of codewords read from a circular buffer are transmitted in a TTI bundle composed of TTIs 0 to 2, and received in base station 200 and relay station 300.

(ACK/NACK Signal Transmission in Base Station 200)

In base station 200, error detecting section 206 performs error detection on received data per TTI.

Then, control information generating section 209 transmits the result of the detection (i.e. an ACK/NACK signal) for the codeword transmitted in the last TTI in a TTI bundle, according to the detecting timing. Here, an ACK/NACK signal for the codeword transmitted in TTI 2, which is the last TTI, is transmitted.

(ACK/NACK signal transmission in relay station 300) In relay station 300, error detecting section 306 performs error detection on received data per TTI.

Then, control information generating section 309 transmits the result of the detection (i.e. an ACK/NACK signal) for the codeword transmitted in the first TTI in a TTI bundle, according to the detecting timing. Here, an ACK/NACK signal for the codeword transmitted in TTI 0, which is the first TTI, is transmitted.

(Scheduling of Retransmission Data from Terminal 100 and Relay Information from Relay Station 300 in Base Station 200)

As described later, in terminal 100, an ACK/NACK signal for the first TTI, which is transmitted from relay station 300, is used as a trigger for preparation for retransmission, and an ACK/NACK signal for the last TTI, which is transmitted from base station 200, is used as a criterion for decision to perform retransmission. That is, as described later, only when NACK signals are transmitted in both the first TTI and the last TTI, terminal 100 retransmits the entire TTI bundle. Therefore, when NACK signals are transmitted in both the first TTI and the last TTI, scheduler 208 in base station 200 secures resources for retransmission using a TTI bundle from terminal 100 (that is, for example, frequency resources for retransmission-scheduled periods TTI 8 to TTI 10).

In addition, as described later, relay station 300 uses the result of the error detection about the first TTI and an ACK/NACK signal for the last TTI, which is transmitted from base station 200, as criteria for decision to perform retransmission processing (relay processing). That is, as described later, when no error is detected in the first TTI and base station 200 transmits NACK, relay station 300 transmits relay information in the retransmission-scheduled period corresponding to the last TTI. Therefore, when relay station 300 transmits an ACK signal for the first TTI and base station 200 transmits a NACK signal for the last TTI, scheduler 208 in base station 200 secures resources for retransmission (relay) using one TTI from relay station 300 (that is, for example, frequency resources for retransmission-scheduled period TTI 10).

(Scheduling of Retransmission Data from Terminal 100 in Relay Station 300)

When NACK signals are transmitted in both the first TTI and the last TTI, terminal 100 retransmits the entire TTI bundle. Therefore, when an error is detected in the first TTI and base station 200 transmits NACK, relay station 300 secures resources for retransmission using a TTI bundle from terminal 100 (that is, for example, frequency resources in retransmission-scheduled periods TTI 8 to TTI 10).

(Processing Associated with Preparation for Retransmission and Decision to Perform Retransmission in Terminal 100)

Terminal 100 determines whether or not to start preparation for retransmission of the entire TTI bundle, based on an ACK/NACK signal for TTI 0, which is transmitted from relay station 300, and determines whether or not to perform retransmission of the prepared codeword for the entire TTI bundle, based on an ACK/NACK signal for TTI 2 transmitted from base station 200.

To be more specific, in terminal 100, control section 110 determines whether or not to command encoding section 102 to start preparation for retransmission of the entire TTI bundle, based on an ACK/NACK signal for TTI 0. Then, when relay station 300 transmits a NACK signal for TTI 0, control section 110 commands encoding section 102 to start preparation for retransmission of the entire TTI bundle. On the other hand, when relay station 300 transmits an ACK signal for TTI 0, terminal 100 does not perform retransmission, so that control section 110 commands encoding section 102 to prepare for transmission of new data.

In addition, in terminal 100, control section 110 determines whether or not to command to encoding section 102 to retransmit the prepared codeword for the entire TTI bundle, based on an ACK/NACK signal for TTI 2. Then, when base station 200 transmits an ACK signal for TTI 2, control section 110 does not command encoding section 102 to retransmit the prepared codeword for the entire TTI bundle. On the other hand, when base station 200 transmits a NACK signal for TTI 2, control section 110 commands encoding section 102 to retransmit the prepared codeword for the entire TTI bundle (see FIG. 7).

(Retransmission from Terminal 100)

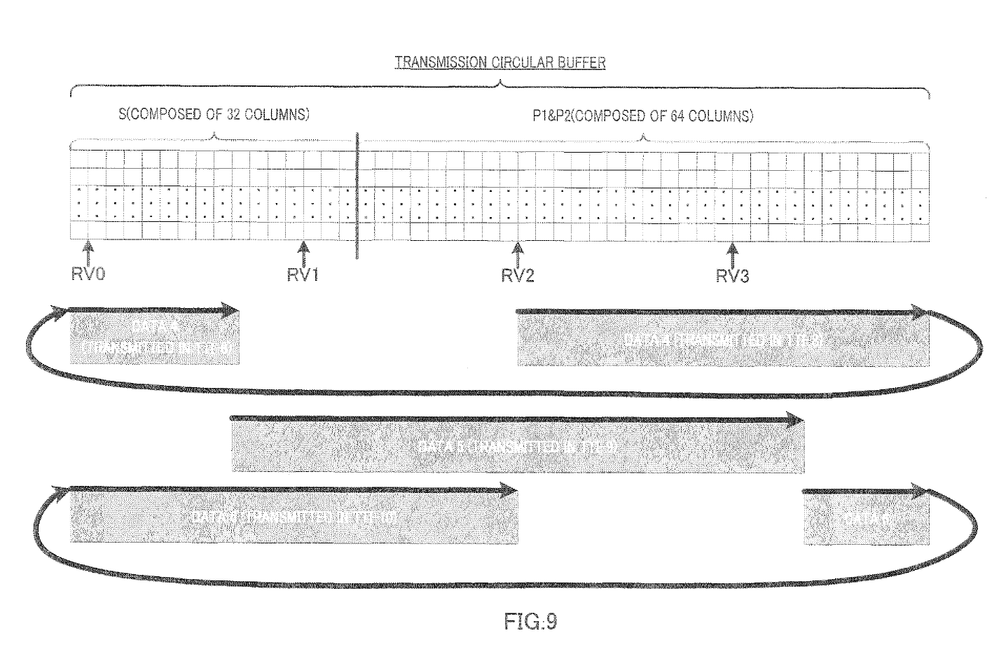

FIG. 9 explains a state in which a codeword is stored in a circular buffer, and a method of reading the codeword from a circular buffer (at the time of retransmission).

At the time of retransmission, encoding section 102 reads a codeword from a different position from the position at the time of last transmission, as a start position, extracts the codeword, and outputs it to modulation section 103. In FIG. 9, RV 2 is the reading start position at the time of the first retransmission.

(Decision to Perform Relay, and Relay Processing in Relay Station 300)

Relay station 300 determines whether or not to perform relay processing, based on the result of the error detection in TTI 0 and an ACK/NACK signal for TTI 2 transmitted from base station 200.

To be more specific, in relay station 300, relay signal processing section 310 determines whether or not to perform relay processing, based on the result of the error detection in TTI 0 and an ACK/NACK signal for TTI 2 transmitted from base station 200. When no error is detected in TTI 0, and base station 200 transmits a NACK signal for TTI 2, relay signal processing section 310 performs relay processing. At this time, relay signal processing section 310 transmits the result of the decoding in TTI 0 in the retransmission-scheduled period corresponding to TTI 2. In this way, relay station 300 performs retransmission instead of terminal 100.

As described above, according to the present embodiment, relay station 300 relays radio communication between a terminal that transmits a radio signal in which a codeword obtained by coding one transmission data is mapped to a TTI bundle composed of a plurality of TTIs, and a base station that receives the radio signal and transmits error detection information about the codeword transmitted in the last TTI in the TTI bundle. Then, in relay station 300, control information generating section 309 transmits error detection information about the codeword transmitted in the first TTI in the TTI bundle.

[Comparative Technique]

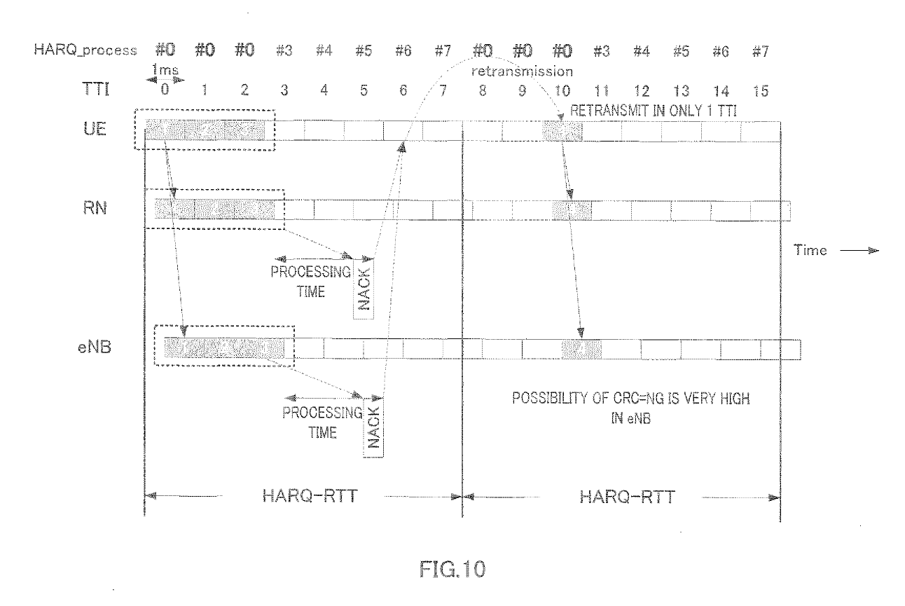

Here, an aspect is possible where relay station 300 transmits the result of the error detection about the codeword transmitted in the last TTI in the TTI bundle, to terminal 100 (see FIG. 10). However, with this aspect, terminal 100 can perform retransmission only in the retransmission-scheduled period corresponding to the last TTI at the time of retransmission. That is, terminal 100 cannot perform retransmission using a TTI bundle. Because, even if preparation for retransmission in the retransmission-scheduled period corresponding to TTIs other than the last TTI starts after receiving a NACK signal in the last TTI, is too late for retransmission in this retransmission-scheduled period. Therefore, it is not possible to perform retransmission using the TTI-bundling technique, so that error characteristics deteriorate in the data receiving side.

By contrast with this, with the present embodiment, relay station 300 transmits error detection information about the codeword transmitted in the first TTI in a TTI bundle, so that terminal 100 can use this error detection information from relay station 300 as a trigger for starting preparing for retransmission. Therefore, terminal 100 can perform retransmission using a TTI bundle.

In addition, base station 200 transmits error detection information about the codeword transmitted in the last TTI in a TTI bundle, so that terminal 100 can use this error detection information from base station 200, as a criterion for decision to perform retransmission.

Moreover, when error detection result information transmitted from base station 200 is NACK, and error detection result information about the first TTI transmitted from relay station 300 is ACK, relay signal processing section 310 transmits relay information in the retransmission-scheduled period corresponding to the last TTI in relay station 300.

By this means, retransmission load is removed from terminal 100. Moreover, communication is performed between relay station 300 and base station 200 with higher quality than between terminal 100 and base station 200, so that it is possible to increase the possibility of successful retransmission.

Here, a case has been explained where relay station 300 transmits error detection information about the codeword transmitted in the first TTI in a TTI bundle, and base station 200 transmits error detection information about the codeword transmitted in the last TTI. However, the present invention is not limited to this. The important thing is that, when base station 200 transmits the result of the error detection about the codeword transmitted in the first TTI, base station 300 transmits the result of the error detection about the codeword transmitted in the second TTI before the first TTI. Here, the second TTI is not the first TTI, terminal 100 does not perform retransmission for the entire TTI bundle, but performs retransmission in the retransmission-scheduled periods corresponding to TTIs from the second TTI to the last TTI. Here, a configuration is adopted in Embodiment 1 where relay station 300 transmits error detection information about the codeword transmitted in the first TTI, because the channel between terminal 100 and relay station 300 exhibits high quality in their communication environment, and therefore an error is not likely to be detected in the first TTI. In addition, in order to employ the principle that the error rate of the code word transmitted in a later TTI in a TTI bundle is lower, a configuration is adopted where base station 200 transmits error detection information in the last TTI.

### Embodiment 2

Although, with Embodiment 1, a configuration has been explained where the result of the error detection about the first TTI obtained in relay station 300 is used as a trigger for starting preparing for retransmission in terminal 100, and criteria to determine which of terminal 100 and relay station 300 performs retransmission, terminal 100 may perform unnecessary transmission, with this configuration. That is, when relay station 300 detects an error in the first TTI, even if the error is, corrected in process of decoding subsequent TTIs (that is, in a state in which ACK should be transmitted in subsequent TTIs), relay station 300 does not perform relay processing. However, if relay station 300 performs error correction on a codeword, it is advantageous to perform retransmission by relay station 300 placed in a good environment for communication with terminal 200.

Therefore, with Embodiment 2, a relay station sequentially transmits not only error detection result information about the codeword transmitted in the first TTI in a TTI bundle, but also error detection result information about the codeword transmitted in the last TTI, according to the detecting timing. Then, the result of the error detection about the last TTI in a relay station is used as criteria to determine which of a terminal and the relay station performs retransmission. By this means, it is possible to perform retransmission in a more advantageous environment.

Here, respective basic configurations of a terminal, a base station and a relay station according to the present embodiment are the same as those of the terminal, the base station and the relay station described in Embodiment 1. Therefore, the terminal, the base station and the relay station according to the present embodiment will be explained with reference to FIG. 4 to FIG. 6.

In terminal 100 according to Embodiment 2, like in Embodiment 1, control section 110 determines whether or not to perform processing, including preparation for retransmission, decision to perform retransmission, retransmission and transmission of new data, based on ACK/NACK information from base station 200 and ACK/NACK information from relay station 300, and outputs control information according to the result of the determination to encoding section 102.

Here, with Embodiment 2, relay station 300 transmits the result of the error detection about the codeword mapped to the last TTI. With Embodiment 2, this result of error detection about the codeword mapped to the last TTI is used as an criterion to determine which of a terminal and a relay station performs retransmission.

That is, when relay station 300 transmits a NACK signal for the first TTI, control section 110 commands encoding section 102 to start preparing for retransmission of the entire TTI bundle.

When at least one of relay station 300 and base station 200 transmits an ACK signal for the last TTI, control section 110 commands encoding section 102 not to perform retransmission. Only when relay station 300 and base station 200 transmit NACK signals for the last TTI, control section 110 commands to perform retransmission.

In addition, when no error is detected in the last TTI and base station 200 transmits a NACK signal for the last TTI, relay signal processing section 310 in relay station 300 according to Embodiment 2 performs relay processing.

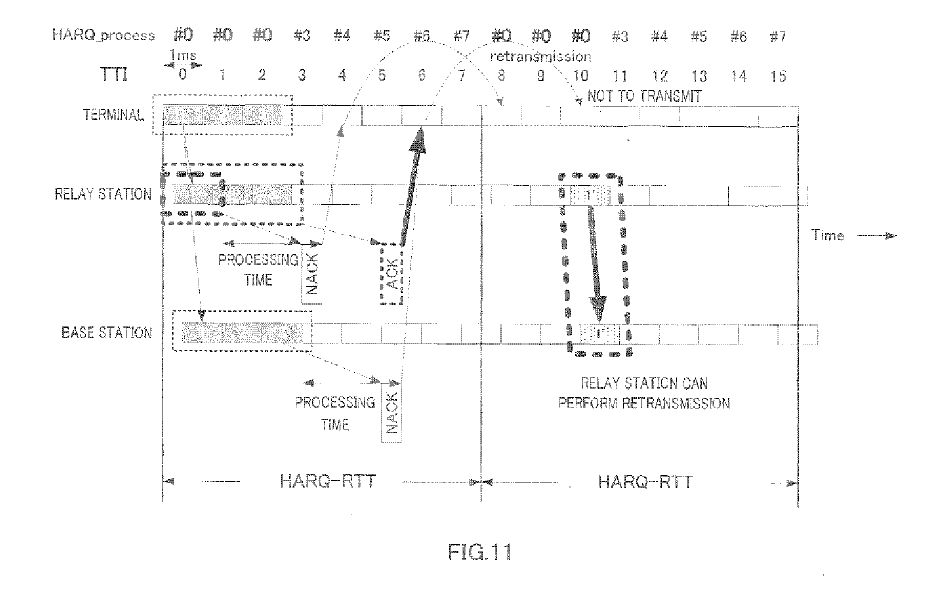

FIG. 11 explains operations of terminal 100, base station 200 and relay station 300 according to Embodiment 2.

As shown in FIG. 11, terminal 100 bundles TTIs 0 to 2 to transmit data.

In relay station 300, error detecting section 306 performs error detection on received data per TTI. Then, control information generating section 309 sequentially transmits ACK/NACK signals for the codeword transmitted in the first TTI and the last TTI in a TTI bundle, according to respective detecting timings. In FIG. 11, a NACK signal is transmitted in TTI 0, and an ACK signal is transmitted in TTI 2.

In addition, in base station 200, error detecting section 206 performs error detection on received data per TTI. Then, control information generating section 209 transmits the result of the error detection in the last TTI, according to the detecting timing. In FIG. 11, a NACK signal is transmitted in TTI 2.

In terminal 100, control section 110 commands to encoding section 102 to start preparing for retransmission of the entire TTI bundle because relay station 300 has transmitted a NACK signal for TTI 0.

Then, control section 110 commands encoding section 102 to stop preparing for retransmission having already been started because relay station 300 has transmitted an ACK signal for TTI 2.

In relay station 300, relay signal processing section 310 transmits retransmission data reencoded using the result of the decoding without an error in the retransmission-scheduled period corresponding to TTI 2, because no error is detected in TTI 2 and base station 200 has transmitted a NACK signal for TTI 2.

As described above, according to the present embodiment, control information generating section 309 in relay station 300 transmits not only an ACK/NACK signal for the codeword transmitted in the first TTI in a TTI bundle, but also an ACK/NACK signal for the codeword transmitted in the last TTI.

By using this ACK/NACK signal for the codeword transmitted in the last TTI, as an criterion to determine which of a terminal and a relay station performs retransmission, retransmission is performed in a more advantageous environment as described above.

### Embodiment 3

With Embodiment 3, a relay station transmits an ACK/NACK signal for only the last TTI in a TTI bundle. Then, after transmitting data using a TTI bundle, a terminal automatically starts preparing for retransmission and determines whether or not to perform retransmission, based on ACK/NACK signals for the last TTI transmitted from a base station and a relay station. Here, the basic configurations of a terminal, a base station and a relay station according to the present embodiment are the same as those of the terminal, the base station and the relay station described in Embodiment 1. Therefore, the terminal, the base station and the relay station according to the present embodiment will be explained, with reference to FIG. 4 to FIG. 6.

In terminal 100 according to Embodiment 3, like in Embodiment 1, control section 110 determines whether or not to perform processing, including decision to perform retransmission, retransmission and transmission of new data, based on ACK/NACK information from base station 200 and ACK/NACK information from relay station 300, and outputs control information according to the result of the determination, to encoding section 102. Here, regarding preparation for retransmission, control section 110 transmits data using a TTI bundle and commands encoding section 102 to start preparing for retransmission. Then, control section 110 determines whether or not to perform retransmission, based on the result of the error detection in the last TTI transmitted from each of base station 200 and relay station 300.

That is, when NACK signals are transmitted from base station 200 and relay station 300, control section 110 commands encoding section 102 to retransmit the entire TTI bundle. If this is not the case, control section 110 commands encoding section 102 not to perform retransmission.

In addition, in relay station 300 according to Embodiment 3, relay signal processing section 310 determines whether or not to perform relay processing, based on the result of the error detection about the last TTI, and the result of the error detection in the last TTI which is transmitted from base station 200. When no error is detected in the last TTI and base station 200 transmits a NACK signal for the last TTI, relay signal processing section 310 performs relay processing. This relay processing is performed in the retransmission-scheduled period corresponding to the last TTI.

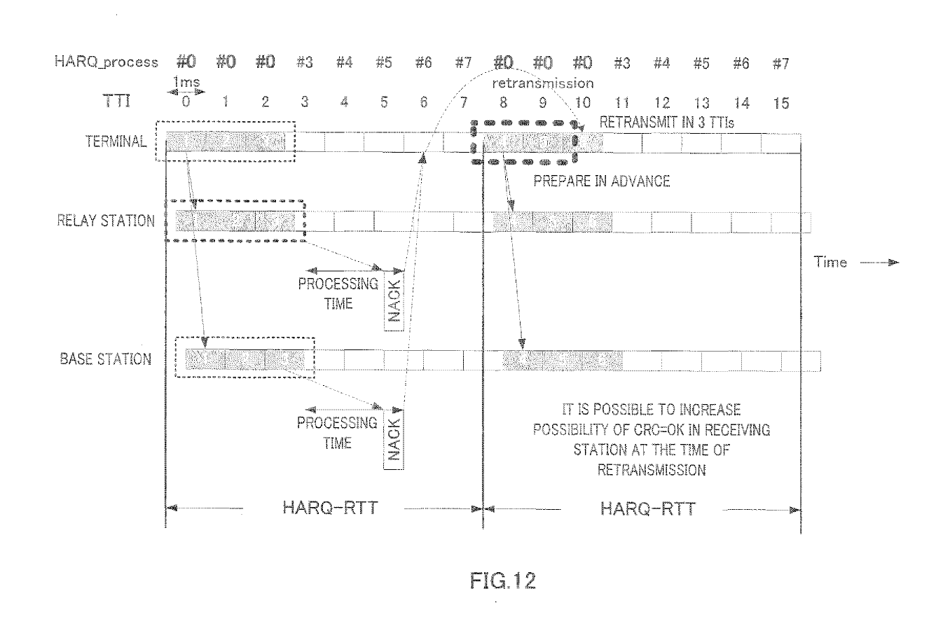

FIG. 12 explains operations of terminal 100, base station 200 and relay station 300 according to Embodiment 3.

As shown in FIG. 12, terminal 100 bundles TTIs 0 to 2 to transmit data. At this time, in terminal 100, control section 110 commands encoding section 102 to start preparing for retransmission of the entire TTI bundle.

In base station 200, error detecting section 206 performs error detection on received data per TTI. Then, control information generating section 209 transmits only the result of the error detection in the last TTI.

In relay station 300, error detecting section 306 performs error detection on received data per TTI. Then, error detecting section 306 transmits only the result of the error detection in the last TTI.

Then, terminal 100 determines whether or not to perform retransmission, based on the result of the error detection in the last TTI transmitted from each of base station 200 and relay station 300. In FIG. 12, control section 110 commands encoding section 102 to retransmit the entire TTI bundle because base station 200 and relay station 300 have transmitted NACK signals. Here, relay station 300 detects no error in the last TTI and base station 200 transmits a NACK signal for the last TTI, relay station 300 performs relay processing.

By this means, it is possible to perform retransmission by deciding more advantageous one between retransmission of the entire TTI bundle by terminal 100 and relay using one TTI by relay station 300, and it is possible to limit the number of times of transmissions of ACK/NACK signals for one TTI bundle from base station 200 and relay station 300, to 1.

### Embodiment 4

With Embodiment 4, a relay station transmits an ACK/NACK signal only about the last TTI in a TTI bundle, like Embodiment 3. Here, although, with embodiment 3, a terminal starts preparing for retransmission immediately after transmitting a TTI bundle to retransmit the entire TTI bundle, one retransmission-scheduled period is skipped and retransmission for the entire TTI bundle is performed in the next retransmission-scheduled period, with embodiment 4. Here, the basic configurations of a terminal, a base station and a relay station according to the present embodiment are the same as those of the terminal, the base station and the relay station described in Embodiment 1. Therefore, the terminal, the base station and the relay station according to the present embodiment will be described with reference to FIG. 4 to FIG. 6.

In terminal 100 according to Embodiment 4, like Embodiment 1, control section 110 determines whether or not to perform processing, including preparation for retransmission, decision to perform retransmission, retransmission and transmission of new data, based on ACK/NACK information from base station 200 and ACK/NACK information from relay station 300, and outputs control information according to the result of the determination, to encoding section 102.

To be more specific, when base station 200 and relay station 300 transmit NACK signals, control section 110 commands encoding section 102 to start preparing for retransmission and then perform retransmission of the entire TTI bundle. Here, this retransmission is performed not in the next first retransmission-scheduled period, but in the second retransmission-scheduled period following the first retransmission-scheduled period.

In addition, in relay station 300 according to Embodiment 4, relay signal processing section 310 determines whether or not to perform relay processing, based on the result of the error detection in the last TTI, and the result of the error detection in the last TTI which is transmitted from base station 200. When no error is detected in the last TTI and base station 200 transmits a NACK signal for the last TTI, relay signal processing section 310 performs relay processing. This relay processing is performed in the retransmission-scheduled period corresponding to the last TTI.

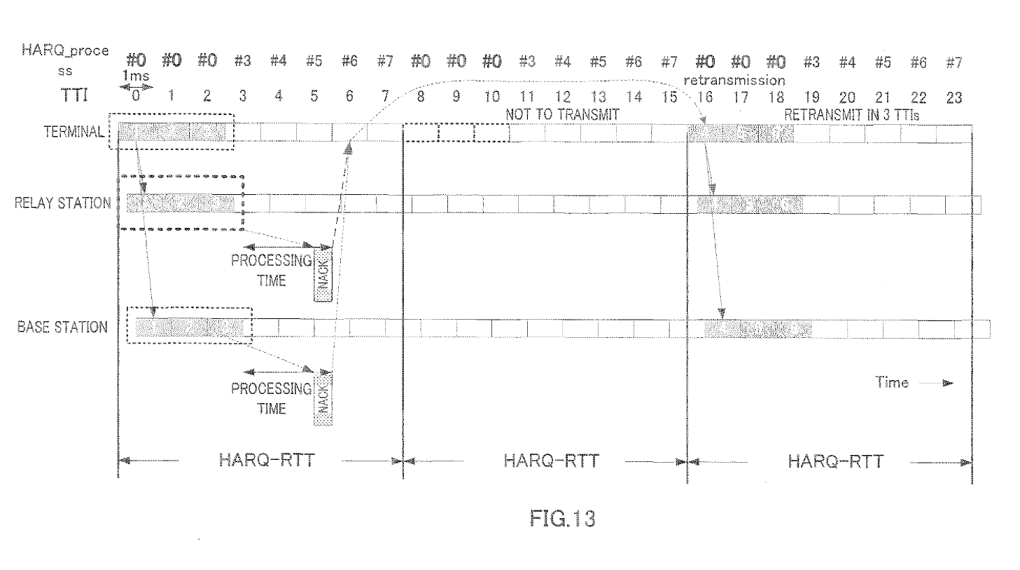

FIG. 13 explains operations of terminal 100, base station 200 and relay station 300 according to Embodiment 4.

As shown in FIG. 13, terminal 100 bundles TTIs 0 to 2 to transmit data.

In base station 200, error detecting section 206 performs error detection on received data per TTI. Then, control information generating section 209 transmits only the result of the error detection in the last TTI.

In relay station 300, error detecting section 306 performs error detection on received data per TTI. Then, error detecting section 306 transmits only the result of the error detection in the last TTI.

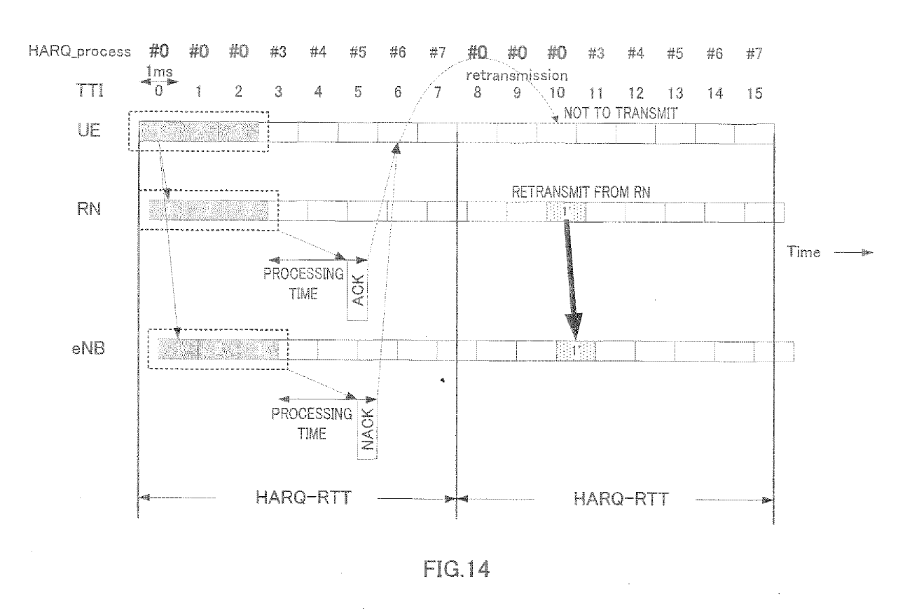

Then, terminal 100 determines whether or not to perform retransmission, based on the result of the error detection about the last TTI transmitted from each of base station 200 and relay station 300. In FIG. 13, base station 200 and relay station 300 transmit NACK signals, so that control section 110 commands encoding section 102 to start preparing for retransmission of the entire TTI bundle and to perform retransmission in the above-described second retransmission-scheduled period (from TTI 16 to TTI 18). Here, relay station 300 detects no error in the last TTI and base station 200 transmits a NACK signal for the last TTI, relay station 300 performs relay processing (see FIG. 14).

By this means, it is possible to perform retransmission by deciding more advantageous one between retransmission of the entire TTI bundle by terminal 100 and relay using one TTI by relay station 300, and it is possible to limit the number of times of transmissions of ACK/NACK signals for one TTI bundle from base station 200 and relay station 300, to 1.

### Another Embodiment

(1) With embodiment 2, relay station 300 transmits the result of the error detection about the codeword transmitted in the first TTI in a TTI bundle and the result of the error detection about the codeword transmitted in the last TIT. By contrast with this, another embodiment is possible where relay station 300 transmits all the results of error detection obtained in TTIs, with respect to a codeword mapped to a TTI bundle.

With this embodiment, terminal 100 uses the result of the error detection about the TTI other than the first TTI and the last TTI, which is transmitted from relay station 300, as a trigger to stop preparation for retransmission having already been started.

That is, when relay station 300 transmits a NACK signal for the first TTI, control section 110 commands encoding section 102 to start preparing for retransmission of the entire TTI bundle. Then, if relay station 300 transmits an ACK signal for the TTI other than the first TTI and the last TTI in a TTI bundle, control section 110 commands encoding section 102 to stop preparation for retransmission having already been started at this time, and to prepare for transmission of new data.

By this means, terminal 100 can stop preparing for retransmission at the time of receipt of an ACK signal without needing to wait for an ACK/NACK signal for the last TTI transmitted from relay station 300, and therefore can reduce power consumption for preparation for retransmission. In addition, a terminal can start preparing for transmission of new data at the time of receipt of an ACK signal, so that it is possible to release a buffer area secured to retransmit data in an early stage.

(2) With Embodiment 3, relay station 300 transmits only an ACK/NACK signal for the codeword transmitted in the last TTI. However, if another embodiment is adopted where relay station 300 transmits an ACK signal for only a TTI in which no error is detected for the first time in a TTI bundle, instead of the last TTI, it is possible to produce the same effect as in Embodiment 3.

In this embodiment, control information generating section 209 transmits an ACK signal for only a TTI in which no error is detected for the first time, with respect to one TTI bundle. Terminal 100 uses this ACK/NACK signal as a criterion to determine which of terminal 100 and relay station 300 performs retransmission.

By this means, terminal 100 can receive an ACK signal from relay station 300 in an earlier stage than in Embodiment 3, and therefore can stop preparing for retransmission at an early stage. Therefore, it is possible to reduce power consumption for preparation for retransmission. In addition, terminal 100 can start preparing for transmission of new data at the time of receipt of an ACK signal from relay station 300, so that it is possible to release a buffer area secured for retransmission data in an early stage.

(3) Here, although, with Embodiment 1, a case has been explained where a predetermined length read from a circular buffer is sixty-four columns, a predetermined length varies depending on the amount of resources assigned by base station 200. In addition, a case has been explained where the column numbers of RVs, which are the positions to read in a circular buffer, are that RV 0 is the third column, RV 1 is the twenty-seventh column, RV 2 is the fifty-first column and RV 3 is the seventy-fifth column, respectively, they may be derived according to other relational equations.

(4) Here, with Embodiments 1 to 4, although cases have been explained where decoding and error detection are performed per TTI, processing to perform decoding and error detection only at the timing to transmit an ACK/NACK signal, is possible.

(5) Here, with Embodiments 1 to 4, although cases have been explained where a TTI bundle is composed of three TTIs, a TTI bundle may be composed of two or more TTIs.

(6) With Embodiments 1 to 4, although descriptions have been explained by assuming a FDD (frequency division duplex) system using varying frequencies between the uplink and downlink, the present invention is not limited to this and is practicable in a TDD (time division duplex) system.

(7) Also, although cases have been described with Embodiments 1 to 4 as examples where the present invention is configured by hardware, the present invention can also be realized by software.

Each function block employed in the description of each of Embodiments 1 to 4 may typically be implemented as an LSI constituted by an integrated circuit. These may be individual chips or partially or totally contained on a single chip. “LSI” is adopted here but this may also be referred to as “IC,” “system LSI,” “super LSI,” or “ultra LSI” depending on differing extents of integration.

Further, the method of circuit integration is not limited to LSI's, and implementation using dedicated circuitry or general purpose processors is also possible. After LSI manufacture, utilization of a programmable FPGA (Field Programmable Gate Array) or a reconfigurable processor where connections and settings of circuit cells within an LSI can be reconfigured is also possible.

Further, if integrated circuit technology comes out to replace LSI's as a result of the advancement of semiconductor technology or a derivative other technology, it is naturally also possible to carry out function block integration using this technology. Application of biotechnology is also possible.

The disclosure of Japanese Patent Application No. 2008-235357, filed on Sep. 12, 2008, including the specification, drawings and abstract, is incorporated herein by reference in its entirety.

### INDUSTRIAL APPLICABILITY

The relay apparatus and the radio communication system according to the present invention are useful to realize new retransmission control when the TTI-bundling technique and the relay technique are adopted for communication between terminals and a base station.

1-6. (canceled)

7. A relay apparatus that relays radio communication between a terminal and a base station, the terminal transmitting a radio signal in which a codeword obtained by encoding one transmission data is mapped into a transmission time interval (TTI) bundle composed of a plurality of TTIs, and the base station receiving the radio signal and transmitting error detection information on the codeword transmitted at a first TTI in the TTI bundle, the relay apparatus comprising:
a decoding section that decodes, per TTI, the codeword mapped into the TTI bundle contained in the received radio signal;
an error detecting section that detects an error of each decoding result; and
a transmission section that transmits information on the error detection result of the codeword transmitted at a second TTI before at least the first TTI in the TTI bundle.

8. The relay apparatus according to claim 7, wherein:
the first TTI is a last TTI in the TTI bundle; and
the transmission section transmits not only the information on the error detection result of the codeword transmitted at the second TTI, but also information on the error detection result of the codeword transmitted at the last TTI.

9. The relay apparatus according to claim 7, wherein:
the first TTI is the last TTI in the TTI bundle; and
the transmission section transmits information on the error detection result of the codeword transmitted at each TTI in the TTI bundle.

10. The relay apparatus according to claim 7, wherein the second TTI is a beginning TTI in the TTI bundle.

11. The relay apparatus according to claim 8, further comprising a relay section that transmits the decoding result obtained by decoding in the TTI bundle, to the base station at a retransmission-scheduled period corresponding to the last TTI, when information on the error detection result transmitted from the base station represents negative acknowledgement and the information, transmitted from the relay station, on error detection result of the codeword transmitted at the last TTI represents acknowledgement.

12. A relay method of relaying radio communication between a terminal and a base station, the terminal transmitting a radio signal in which a codeword obtained by encoding one transmission data is mapped into a transmission time interval (TTI) bundle composed of a plurality of TTIs, and the base station receiving the radio signal and transmitting error detection information on the codeword transmitted at a first TTI in the TTI bundle, the relay method comprising:
decoding, per TTI, the codeword mapped into the TTI bundle contained in the received radio signal;
detecting an error of each decoding result; and
transmitting information on the error detection result of the codeword transmitted at a second TTI before at least the first TTI in the TTI bundle.
